(19) United States
(12) Patent Application Publication
(10) Pub. No.: US 2017/0052274 A1
(43) Pub. Date: Feb. 23, 2017

(54) RESIDENT PRESENCE-ABSENCE STATE DETERMINATION DEVICE, DELIVERY SYSTEM, METHOD FOR DETERMINING RESIDENT PRESENCE-ABSENCE STATE, PROGRAM FOR DETERMINING RESIDENT PRESENCE-ABSENCE STATE, AND TERMINAL FOR DELIVERY

(71) Applicant: NEC Corporation, Tokyo (JP)

(72) Inventors: Yuichiro FUKUBAYASHI, Tokyo (JP); Yasuaki KONDO, Tokyo (JP)

(21) Appl. No.: 15/119,359

(22) PCT Filed: Feb. 13, 2015
(86) PCT No.: PCT/JP2015/000672

§ 371 Date: Aug. 16, 2016

(30) Foreign Application Priority Data
Feb. 17, 2014 (JP) 2014-027686

(51) Int. Cl. G01V 3/38; G01V 3/04; G01R 31/36; G05B 15/02; H02J 7/00

(52) U.S. Cl. CPC G01V 3/38; G05B 15/02; H02J 7/0047; G01R 31/3606; G01V 3/04; H02J 2007/005

(57) ABSTRACT

In order to provide a resident presence-absence state determination device which determines an resident presence-absence state with a high degree of accuracy, a delivery system, a method for determining an resident presence-absence state, a recording medium recording a program for determining an resident presence-absence state, and a terminal for delivery, the present invention provides the resident presence-absence state determination device including charge/discharge information acquisition means for acquiring charge/discharge information indicating a discharging status of an electricity storage device for supplying an electric power to a load placed in a house and resident presence-absence state determination means for determining a resident presence-absence state of the house based on the charge/discharge information.

### TECHNICAL FIELD

The present invention relates to a resident presence-absence state determination device, a delivery system, a method for determining a resident presence-absence state, a program for determining a resident presence-absence state, and a terminal for delivery.

### BACKGROUND ART

In a delivery service to deliver goods, if a delivery destination resident is not at home, a delivery efficiency decreases and delivery cost increase. Accordingly, a technology to determine a resident presence-absence state of the house or the like that is the delivery destination exists. In patent literature 1, it is disclosed a system for calculating the probability that the resident is at home based on information on electric power usage measured by an automated meter reading device.

A resident presence probability calculation system disclosed in patent literature 1 determines a resident presence-absence state based on a value of the electric power usage and the variation thereof detected by an automated meter reading system. Further, by additionally taking into consideration the behavioral characteristic of each home based on information on past electric power usage, a “resident presence probability” at a specified future time is calculated based on the information on past electric power usage. It is preferable that the “resident presence probability” is provided to a service user and the service user makes a plan to visit a user's home by using the “user presence probability” as a criterion of determination.

### CITATION LIST

### Patent Literature

[PTL 1] Japanese Patent Application Laid-Open No. 2012-181789
[PTL 2] International Publication No. 2006/006223
[PTL 3] Japanese Patent Application Laid-Open No. 2001-294309
[PTL 4] Japanese Patent Application Laid-Open No. 2001-188984

### SUMMARY OF INVENTION

### Technical Problem

In patent literature 1, the resident presence-absence state is determined based on the electric power usage (the usage of purchased electric power supplied by a system or an electric power supplier) detected by the automated meter reading system. However, when the resident presence-absence state is determined based on the electric power usage detected by the automated meter reading system, a determination result with sufficient accuracy cannot be obtained.

This is because an electricity storage device is used in a home or the like. The electricity storage device stores the electric power supplied from the system in a storage battery and discharges the electric power when electric power is required. By using this function, the electricity storage device is used as a back-up power supply used when electric power is lost, used for the leveling of electric power usage, or used for another purpose. The leveling of electric power usage is a process in which the electric power supplied from the system is stored in the storage battery during the night and the electric power is discharged from the storage battery during periods of peak demand for electricity in the daytime in order to reduce a peak value of electric power usage. When the leveling of electric power usage is performed by using the electricity storage device, the peak value of electric power usage is reduced over one day and the variation of electric power usage detected by the automated meter reading system becomes small. Accordingly, it is difficult to determine the resident presence-absence state based on the value of the electric power usage and the variation thereof.

An object of the present invention is to provide a resident presence-absence state determination device which can solve the above-mentioned problem and determine the resident presence-absence state with a high degree of accuracy, a delivery system, a method for determining a resident presence-absence state, a program for determining a resident presence-absence state, and a terminal for delivery.

### Solution to Problem

The present invention is a resident presence-absence state determination device comprising:

charge/discharge information acquisition means for acquiring charge/discharge information indicating a charging status or a discharging status of an electricity storage device for supplying an electric power to a load placed in a house and resident presence-absence state determination means for determining a presence-absence state of a resident in the house based on the charge/discharge information.

A delivery system according to the present invention comprises electricity storage means for supplying an electric power to a load placed in a house that is a delivery destination, charge/discharge information acquisition means for acquiring charge/discharge information indicating a charging status or a discharging status of the electricity storage means, resident presence-absence state determination means for determining a presence-absence state of a resident in the house based on the charge/discharge information, and means for outputting a delivery route including the house to which it is determined that the resident is in the house.

The present invention is a method for determining a resident presence-absence state in which charge/discharge information indicating a charging status or a discharging status of an electricity storage device for supplying an electric power to a load placed in a house is acquired and a resident presence-absence state of the house is determined based on the charge/discharge information.

A recording medium recording a program for determining a resident presence-absence state of the present invention is a recording medium recording a program which causes a computer to function as a resident presence-absence state determination device for determining a resident presence-absence state of a house wherein the recording medium is the recording medium recording the program for determining the resident presence-absence state which causes the computer to perform a process in which charge/discharge information indicating a charging status or a discharging status of an electricity storage device for supplying an electric power to a load placed in the house is acquired and a process in which the resident presence-absence state of the house is determined based on the charge/discharge information.

The present invention is a terminal for use in a delivery system comprising: means for transmitting a request in which a house that is a delivery destination and a delivery time at which a delivery is performed to the delivery destination are specified, means for receiving an presence-absence state of a resident in the house, the presence-absence state being determined based on charge/discharge information indicating a charging status or a discharging status of an electricity storage device for supplying an electric power to a load placed in the house and means for outputting a delivery route including the house as to which the presence-absence state is determined that the resident is present in the house.

### Advantageous Effects of Invention

By using the present invention, the resident presence-absence state can be determined with a high degree of accuracy.

### BRIEF DESCRIPTION OF DRAWINGS

FIG. 1 is a figure showing an example of an exemplary embodiment of the present invention.

FIG. 2 is a figure showing an example of a configuration of a house 100 according to an exemplary embodiment of the present invention.

FIG. 3 is a figure showing an example of a function block of a resident presence-absence state determination device 105 according to an exemplary embodiment of the present invention.

FIG. 4 is a figure showing an example of charge/discharge information of the present invention.

FIG. 5 is a figure showing an example of an operational flow of a resident presence-absence state determination device according to an exemplary embodiment of the present invention.

FIG. 6 is a figure showing an example of an electric power usage and a discharged electric power amount in an exemplary embodiment of the present invention.

FIG. 7 is a figure showing an example of an electric power usage, a discharged electric power amount, and a charged electric power amount in an exemplary embodiment of the present invention.

FIG. 8 is a figure showing an example of a function block of a resident presence-absence state determination device according to an exemplary embodiment of the present invention.

FIG. 9 is a figure showing an example of an operational flow of a resident presence-absence state determination device according to an exemplary embodiment of the present invention.

FIG. 10 is a figure showing an example of a function block of a resident presence-absence state determination device according to an exemplary embodiment of the present invention.

FIG. 11 is a figure showing an example of an operational flow of a resident presence-absence state determination device according to an exemplary embodiment of the present invention.

FIG. 12 is a figure showing an example of an electric power usage, a discharged electric power amount, and a generated electric power amount in an exemplary embodiment of the present invention.

FIG. 13 is a figure showing an example of a hardware configuration of a resident presence-absence state determination device of the present invention.

### DESCRIPTION OF EMBODIMENTS

An exemplary embodiment of the present invention will be described in detail below. Further, the same reference numbers are used for the elements having the same function as the exemplary embodiment previously described in the specification and the description of the element will be appropriately omitted.

### First Exemplary Embodiment

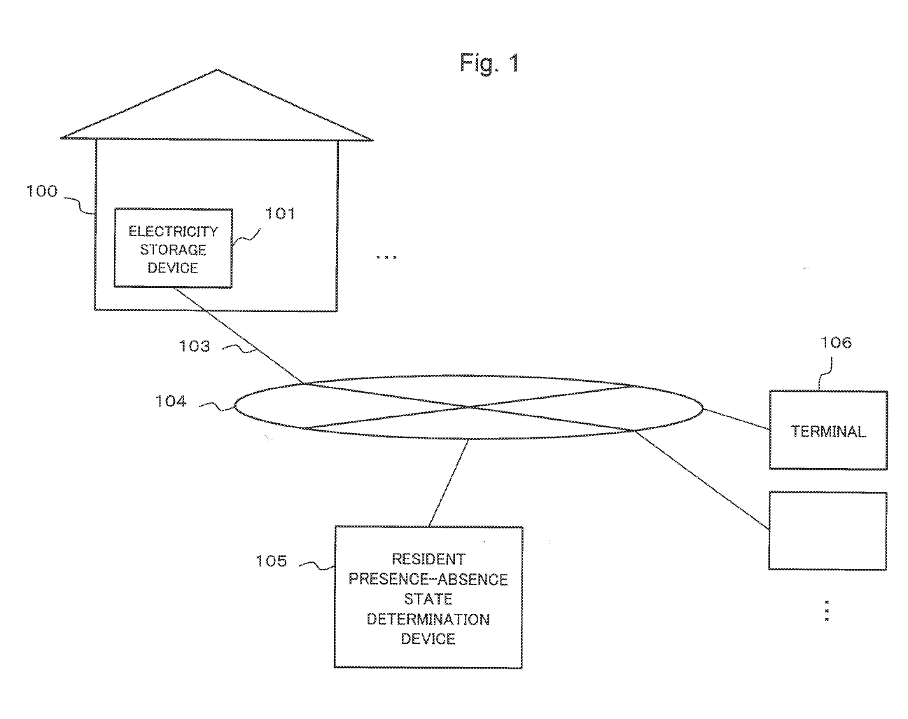

A first exemplary embodiment of the present invention will be described. FIG. 1 shows an example of a system to which a resident presence-absence state determination device of the present invention is applied. A resident presence-absence state determination device 105 of the present invention is connected to a user's house 100 via a network 104 and a communication wire 103. An electricity storage device 101 is installed in the house 100. The resident presence-absence state determination device 105 is connected to a terminal 106 via the network 104 and the communication wire 103.

In the system to which the present invention is applied, the terminal 106 transmits a resident presence-absence state determination request in which a predetermined time (or a time zone) of the house 100 is specified to the resident presence-absence state determination device 105. The resident presence-absence state determination device 105 acquires the charge/discharge information from the electricity storage device 101 of the specified house 100 and determines a resident presence-absence state at the specified time when the user of the specified house agrees. The resident presence-absence state includes a state in which a residentiary is presence in the object house 100 and a state in which a residentiary is absence in it. The determination of the resident presence-absence state includes the determination of the state in which the residentiary is present in the house 100 and the determination of the state in which the residentiary is absent in the house 100. The resident presence-absence state determination device 105 notifies the terminal 106 of a determination result of the resident presence-absence state.

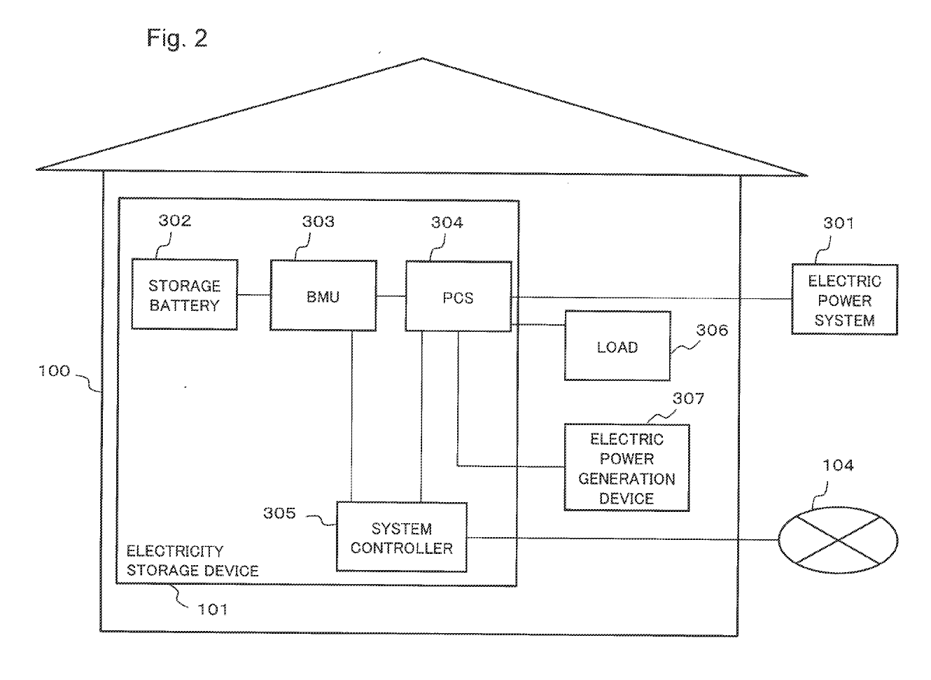

FIG. 2 shows an example of the house 100. Referring to FIG. 2, the house 100 includes the electricity storage device 101, a load 306, and an electric power generation device 307. The electricity storage device 101 includes a storage battery 302, a BMU (Battery Management Unit) 303, a PCS (Power Condition System) 304, and a system controller 305. The electricity storage device 101 stores the electric power supplied from an electric power system 301 and the electric power generation device 307 and supplies the stored electric power to the load 306. The electric power is supplied to the load 306 from the system 301, the electricity storage device 101, and the electric power generation device 307.

The resident presence-absence state determination device 105 of the present invention determines the resident presence-absence state of the user's house when the user agrees.

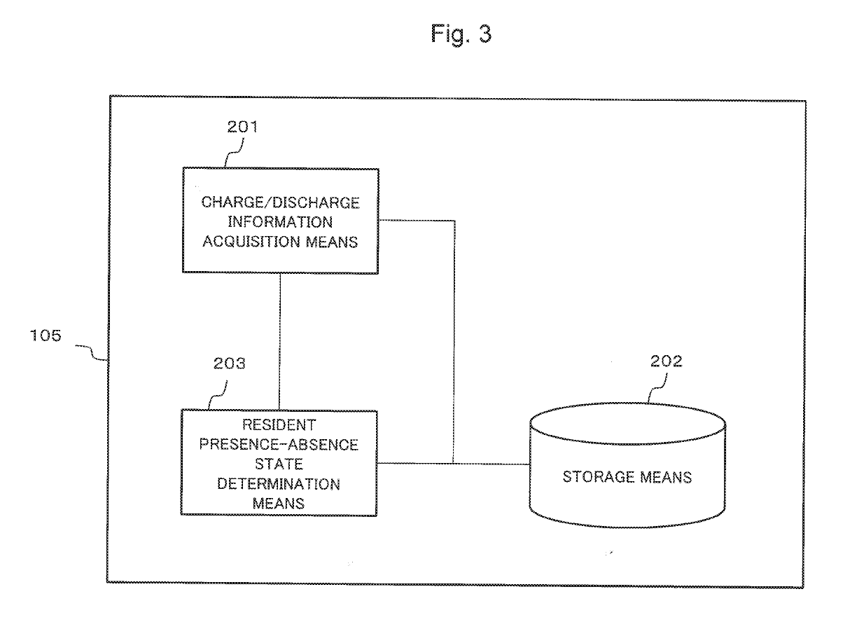

FIG. 3 shows an example of a function block diagram of the resident presence-absence state determination device 105 according to the first exemplary embodiment. Referring to FIG. 3, the resident presence-absence state determination device 105 includes charge/discharge information acquisition means 201, resident presence-absence state determination means 203, and storage means 202.

The charge/discharge information acquisition means 201 acquires the charge/discharge information on the electricity storage devices 101 from the electricity storage devices 101. The charge/discharge information acquisition means 201 transmits the charge/discharge information to the resident presence-absence state determination means 203. The charge/discharge information is information indicating a charging status or a discharging status (hereinafter, also referred to as charging/discharging status) of the electricity storage device 101. The charging/discharging status shows a state in which the electricity storage device 101 supplies the electric power to the load (excluding self-discharge), a state in which charging is performed, the discharged electric power amount, the charged electric power amount, a discharged electric power, a charged electric power, variations thereof, and the like. The charge/discharge information acquisition means 201 transmits the charge/discharge information to the storage means 202 and the storage means 202 may store the charge/discharge information.

The charge/discharge information includes the following information and the like.
information indicating a discharge state
information indicating a non-discharge state (a charge state or a waiting state)
an electric energy (Wh) discharged by the electricity storage device in a time zone with a unit time period
an electric energy (Wh) stored in the electricity storage device in a time zone with a unit time period
an electric power (W) discharged by the electricity storage device
an electric power (W) stored in the electricity storage device
a time at which the electricity storage device starts to store the electric power or starts to supply the electric power to the load (including a scheduled time at which the electric power will be stored in the electricity storage device or supplied to the load, hereinafter, referred to as a charge/discharge start time)
a time at which the charge finishes or the discharge finishes (including a scheduled charge finish time and a scheduled discharge finish time, hereinafter, referred to as a charge/discharge finish time)
a time elapsing from the charge/discharge start time
variation of the discharged electric power amount or variation of the charged electric power amount
variation of the discharged electric power or variation of the charged electric power
a charge/discharge schedule of the electricity storage device
a value calculated from a past record value of the charged electric power amount or the discharged electric power amount of the electricity storage device

and
a predicted value calculated based on at least one or more of these information

The charge/discharge information acquisition means 201 acquires the charge/discharge information. However, means for acquiring it is not limited in particular. The charge/discharge information acquisition means 201 may always acquire a charge/discharge state of an electricity storage system from the electricity storage device 101. Alternatively, the charge/discharge information acquisition means 201 may periodically (for example, every 30 minutes, every 3 hours) acquire the state of charge/discharge. Further, the charge/discharge information acquisition means 201 may always, periodically, or irregularly acquire the charged electric power amount or the discharged electric power amount of the electricity storage device 101.

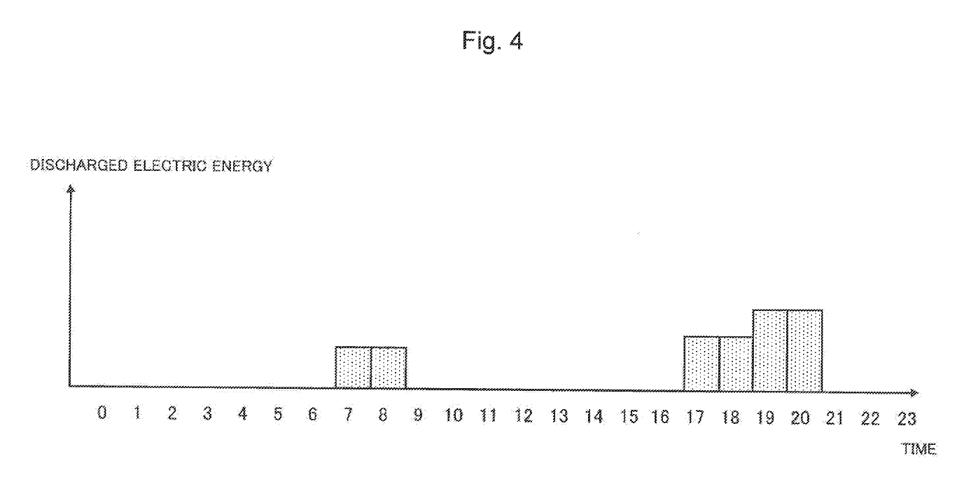

FIG. 4 is a figure showing an example of the charge/discharge information. FIG. 4 is a graph of electric energy (Wh) discharged by the electricity storage device versus time. FIG. 4 shows a discharge schedule of the electricity storage device 101 on a certain day.

Referring to FIG. 4, the electricity storage device 101 discharges the electric power in a time zone from 7 am to 9 am and a time zone from 5 pm to 8 pm.

Further, the expression of “time zone from 7 am to 8 am” shows the time zone from 7:00 to 7:59 (hereinafter, similarly described). However, the time length of each time zone is not limited to the time length described above. It may be for example, 30 minutes or 3 hours.

In the discharge schedule, the discharge start time and the discharge finish time or the time zone in which discharge is performed is set. In the discharge schedule, the discharged electric power amount, a charging time zone, the charged electric power amount, or the like other than the above-mentioned items may be set.

In FIG. 3, the storage means 202 of the resident presence-absence state determination device 105 stores the charge/discharge information.

Further, a storage unit 202 stores information (for example, information indicating whether or not the user permits the determination of the resident presence-absence state) required when the resident presence-absence state determination means 203 determines the resident presence-absence state. The storage means 202 may be placed separately from the resident presence-absence state determination device 105. For example, with respect to the information indicating whether or not the user permits the determination of the resident presence-absence state, the user inputs the information indicating whether or not the user permits the determination of the resident presence-absence state from the electricity storage device 101 and the resident presence-absence state determination device 105 acquires the information indicating the permission of the user from the electricity storage device 101. The information indicating the permission of the user is stored in the storage means 202. The resident presence-absence state determination means 203 reads the information indicating the permission of the user from the storage means 202 and determine whether or not the user permits the determination of the resident presence-absence state.

The resident presence-absence state determination means 203 determines the resident presence-absence state of the house to which the user permits the determination of the resident presence-absence state.

The resident presence-absence state determination means 203 determines the resident presence-absence state based on the charge/discharge information. The resident presence-absence state determination means 203 determines whether or not the electricity storage system is in the discharge state based on the charge/discharge information. When the electricity storage system is in the discharge state, it is determined that the user is at home. It can be determined whether or not the electricity storage system is in the discharge state by using a commonly used method such as a method in which a value of the discharged electric power of the electricity storage device is measured or the like. There is a high possibility that a state in which the electricity storage device 101 supplies an electric power to the load placed in the house is a state in which the user is at home and uses the load (for example, an electrical appliance). Accordingly, in such case, it is determined that the user is at home.

The resident presence-absence state determination means 203 can determine (estimate) the resident presence-absence state at a time in the future. For example, the resident presence-absence state determination means 203 determines whether or not the electricity storage device 101 is in the discharge state at a time in the future by using the discharge schedule in which the discharge start time and the discharge finish time of the electricity storage device 101 are specified. When it is determined that the electricity storage device 101 is in the discharge state, it is determined that the user will be at home. This will be described more in detail with reference to FIG. 4. FIG. 4 shows the discharge schedule of the electricity storage device 101 on a certain day. The time zone from 7 am to 9 am and the time zone from 5 pm to 9 pm are the time zones for discharge. In a case in which the resident presence-absence state is determined at 10 am, the electricity storage device 101 is not in the discharge state at 10 am because the time of 10 am is not in the time zone for discharge. Therefore, the resident presence-absence state determination means 203 determines that the user will be not at home at 10 am. In a case in which the resident presence-absence state is determined at 7 pm, the resident presence-absence state determination means 203 determines that the user will be at home because the time of 7 pm is in the time zone for discharge.

Further, the resident presence-absence state determination means 203 estimates whether or not the electricity storage device 101 at a time in the future will be in the discharge state based on the past record value of the discharged electric power amount measured at a time, day of the week, month, season, and weather condition in the past that correspond to a time, day of the week, month, season, and weather condition in the future. For example, it is assumed that the resident presence-absence state will be determined at 10 am on Monday of January 30th. When it is estimated that a probability that a time of 10 am is in the time zone in which discharge is performed exceeds a predetermined value based on the discharge schedule for example, on Monday in December and January before January 30th, the resident presence-absence state determination means 203 determines that there is a high possibility that the time of 10 am on Monday of January 30th is in the time zone in which discharge is performed and the user will be at home.

The timing at which the resident presence-absence state determination means 203 determines the resident presence-absence state is not limited in particular. For example, the resident presence-absence state determination means 203 may always monitor the charge/discharge information and determine the resident presence-absence state when the charge/discharge information changes. Alternatively, the resident presence-absence state may be determined at the timing specified by the terminal or at the time or time interval set in advance based on a request from the terminal. Further, the user may specify the timing or time interval of the determination. Further, the once determined resident presence-absence state may be updated according to the change of the charge/discharge information.

The resident presence-absence state determination means 203 determines the resident presence-absence state at the time specified by the request from the terminal. Alternatively, the resident presence-absence state determination means 203 may determine the resident presence-absence state at the time specified by the user.

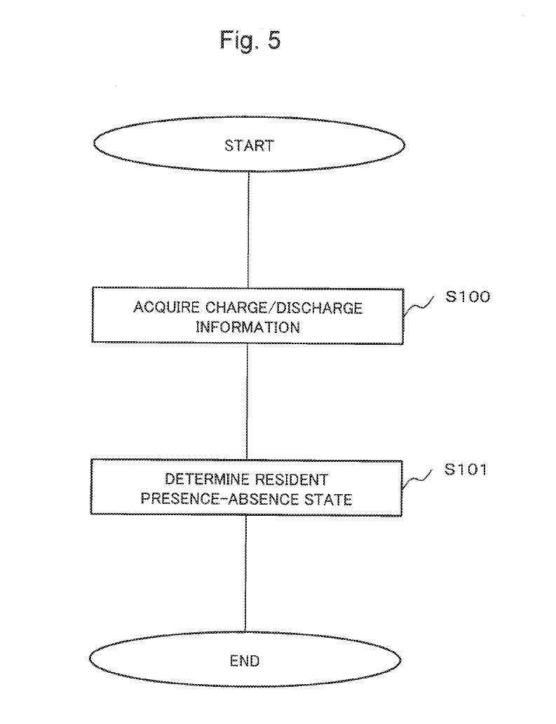

The flow of the operation of the resident presence-absence state determination device 105 according to this exemplary embodiment will be described by using a flowchart shown in FIG. 5. In step S100, the charge/discharge information acquisition means 201 acquires the charge/discharge information from the electricity storage device 101 through a communication line. The charge/discharge information acquisition means 201 transmits the charge/discharge information to the resident presence-absence state determination means 203. Alternatively, the charge/discharge information acquisition means 201 may transmit the charge/discharge information to the storage means 202 and the charge/discharge information may be stored in the storage means 202. In step S101, the resident presence-absence state determination means 203 determines whether or not the electricity storage system is in the discharge state based on the charge/discharge information and determine that the user is at home when the electricity storage system is in the discharge state. The resident presence-absence state determination means 203 stores a determination result in the storage means 202.

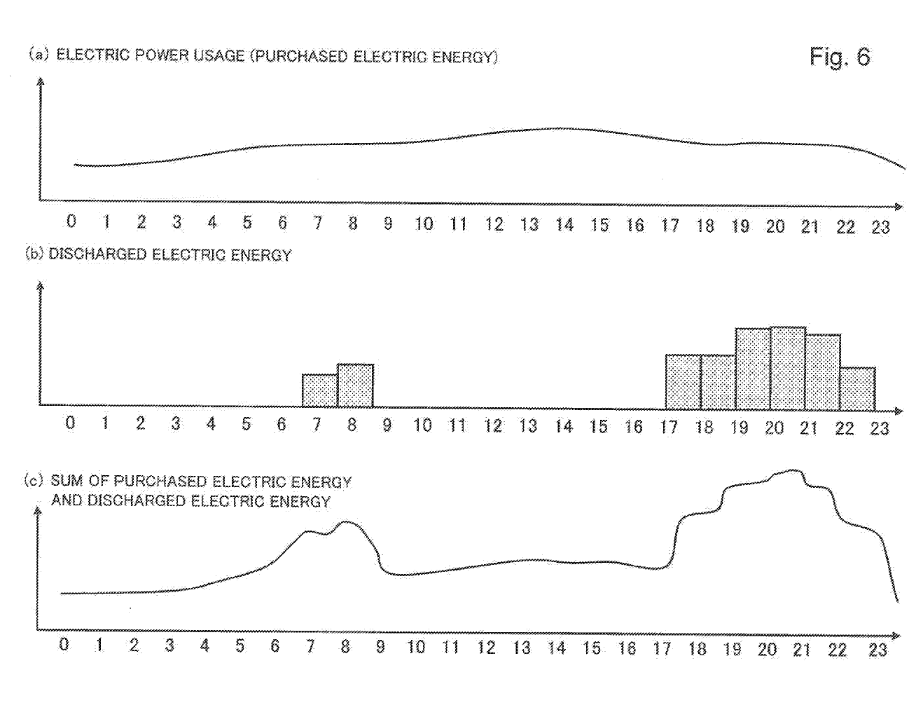

The effect of this exemplary embodiment will be described. FIG. 6(a) shows the electric power usage (the usage of the purchased electric power supplied by the system or the electric power supplier) in the house 100. FIG. 6(a) is a graph of electric power usage (Wh) versus time. FIG. 6(b) shows the discharged electric power amount of the electricity storage device 101. FIG. 6(c) shows a sum of the electric power usage (the purchased electric power amount) shown in FIG. 6(a) and the discharged electric power amount shown in FIG. 6(b). Namely, FIG. 6(c) shows the electric energy consumed in the house 100.

As shown in FIG. 6(c), the electric energy consumed in the house 100 increases in the time zone from 7 am to 9 am (for example, the user gets up, puts a heater on, does the laundry, and performs another action and whereby the consumed electric power increases). The consumed electric power decreases after 9 o'clock (for example, when the user goes out, the consumed electric power decreases). The consumed electric power increases in the time zone from 5 pm to 11 pm again (for example, when the user returns to the house, the user puts a heater on, switches on the television, and performs another action and whereby the consumed electric power increases). In contrast, as shown in FIG. 6(b), the electricity storage device 101 discharges the electric power in the time zone in which a large electric energy is consumed in the house 100 to supply the required electric power. By this operation, as shown in FIG. 6(a), the electric power usage (the purchased electric power amount) is leveled by the discharge of the electricity storage device and the variation of the electric power usage becomes small. In such case, it is difficult to determine the resident presence-absence state based on the electric power usage. In this exemplary embodiment, the resident presence-absence state is determined based on the charge/discharge information of the electricity storage device. Accordingly, as the example described above, the resident presence-absence state can be determined with a high degree of accuracy while suppressing the peak of the electric power usage by the discharge of the electricity storage device 101 even when the user is at home and consumes the electric power in the house.

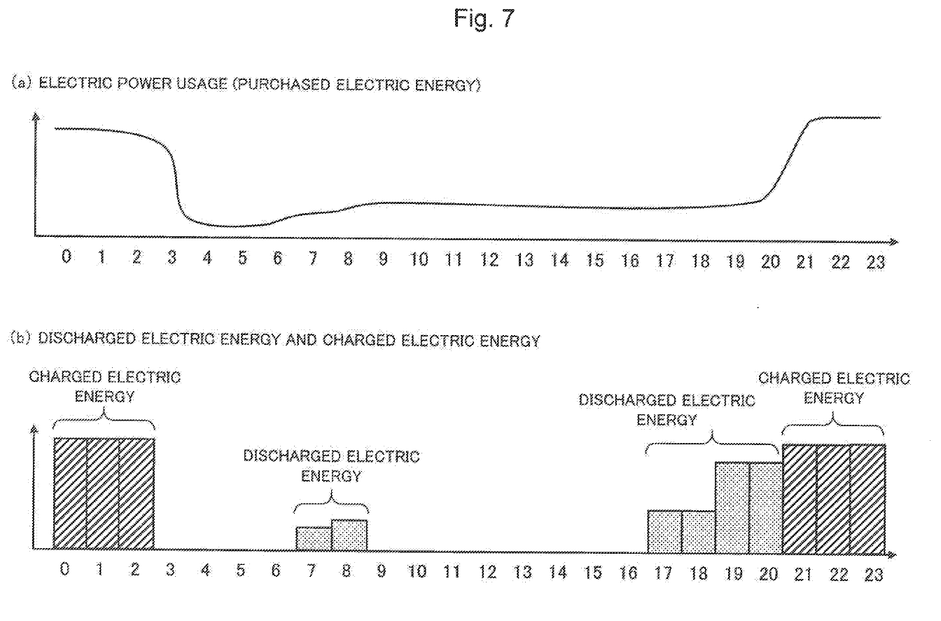

FIG. 7 is another figure showing an effect of this exemplary embodiment. FIG. 7(a) shows the electric power usage (the usage of the purchased electric power supplied by the system or the electric power supplier) in the house 100. FIG. 7(a) is a graph of electric power usage (Wh) versus time. FIG. 7(b) shows the discharged electric power amount (crosshatched bar graph) and the charged electric power amount (hatched bar graph) of the electricity storage device.

Referring to FIG. 7 (a), the electric power usage (the purchased electric power amount) is large in the time zone from 0 am to 3 am and the time zone after 9 pm. The electric power usage is small in the time zone other than the above-mentioned time zone. Namely, it is leveled. This is because as shown in FIG. 7(b), the electric power from the system is stored in the electricity storage device 101 in the night time zone (from 0 am to 3 am and after 9 pm) in which the electric power rate is low. In the time zone (composed of the time zone from 7 am to 9 am and the time zone from 5 pm to 8 pm) in which the electric power rate is high, the electricity storage device 101 discharges the electric power. Therefore, the usage of the electric power supplied from the system can be reduced and the electricity charges can be reduced. In such case, when the resident presence-absence state is determined based on the change of the electric power usage shown in FIG. 7(a), the resident presence-absence state cannot be correctly determined. For example, in FIG. 7(a), because the electric power usage is large in the time zone from 0 am to 3 am and the time zone from 9 pm to 11 pm, it is determined that the user will be at home. However, FIG. 7(a) may show a case in which in the time zone from 0 am to 3 am and the time zone from 9 pm to 11 pm, the load (electric appliance) is not used, the electric power is stored in the electricity storage device, and the user may not be at home. On the other hand, in this exemplary embodiment, the resident presence-absence state is determined by using the charge/discharge information. In an example shown in FIG. 7, it is determined that the user is at home in the time zone from 7 am to 9 am and the time zone from 5 pm to 8 pm that are the discharge time zones of the electricity storage device. Therefore, by using this exemplary embodiment, the resident presence-absence state can be correctly determined.

### Second Exemplary Embodiment

The resident presence-absence state determination device 105 according to a second exemplary embodiment is the same as the resident presence-absence state determination device 105 according to the first exemplary embodiment shown in FIG. 3.

The operation of the resident presence-absence state determination means 203 according to this exemplary embodiment is different from the operation of the resident presence-absence state determination means 203 according to the first exemplary embodiment. However, the operation and function of means other than the resident presence-absence state determination means 203 according to this exemplary embodiment is the same as those of the means according to the first exemplary embodiment.

The resident presence-absence state determination means 203 compares the discharged electric power amount of the electricity storage device 101 with a predetermined reference value by using the charge/discharge information and determine the resident presence-absence state. For example, when the discharged electric power amount at a certain time is greater than the reference value, it is determined that the user is at home at the time. The reference value can be appropriately set. For example, based on the history of the discharged electric power amount for each unit time zone in a predetermined period, a fifty percent value of the average value of the discharged electric power amount in the unit time zone may be used as the reference value. Various methods can be used for setting the reference value. For example, the fifty percent value of the average value of the discharged electric power amount in the same time zone in the predetermined past period or a seventy percent value of the average value of the discharged electric power amount in the same time zone on the same day of the week in the predetermined past period can be used as the reference value. By this method, the appropriate value which reflects the discharged electric power amount which changes according to a life pattern and the season can be set as the reference value and whereby the accuracy of the determination of the resident presence-absence state can be increased. Various periods such as two weeks, one month, and the like can be set as the predetermined past period.

Further, the reference value can be appropriately set by the user that uses the electricity storage device 101. For example, the user selects the load used when the user is at home and can set the reference value of the discharged electric power amount based on the discharged electric power amount to the load. Further, the user selects the loads always used when the user is not at home and sets the reference value of the discharged electric power amount based on the sum of the discharged electric power amounts to these loads and when the discharged electric power amount is equal to or smaller than the reference value, it can be determined that the user is not at home.

Further, the resident presence-absence state determination means 203 may determine the resident presence-absence state according to the variation of the discharged electric power amount of the electricity storage device based on the charge/discharge information. For example, when the variation of the discharged electric power amount exceeds the reference value, it can be determined that the user is at home or the user is not at home. The discharged electric power amount may greatly change when the user returns to the house 100 or leaves the house 100. For example, when the discharged electric power amount increases and exceeds the reference value, it can be determined that the user is at home. Further, when a predetermined value or more of the electric power is being discharged after the time at which the discharged electric power amount increases, it may be determined that the user is at home. In contrast, when the discharged electric power amount decreases to a value smaller than the reference value, it can be determined that the user is not at home. In this case, the variation of the discharged electric power amount in the past, the variation determined by the user, or the like can be appropriately set to the reference value. The reference value is set in advance and stored in the storage means 202. The resident presence-absence state determination means 203 acquires the reference value from the storage means 202. The operation of the resident presence-absence state determination device according to this exemplary embodiment is similar to the operation of the resident presence-absence state determination device according to an exemplary embodiment 1. Therefore, the description will be omitted.

This exemplary embodiment has an effect that is the same as that of the exemplary embodiment 1. Further, in this exemplary embodiment, the resident presence-absence state is determined based on the value and variation of the discharged electric power amount. Therefore, the resident presence-absence state can be determined with a higher degree of accuracy.

### Third Exemplary Embodiment

The resident presence-absence state determination device 105 according to a third exemplary embodiment determines the resident presence-absence state by additionally using information of the power consumption of the load.

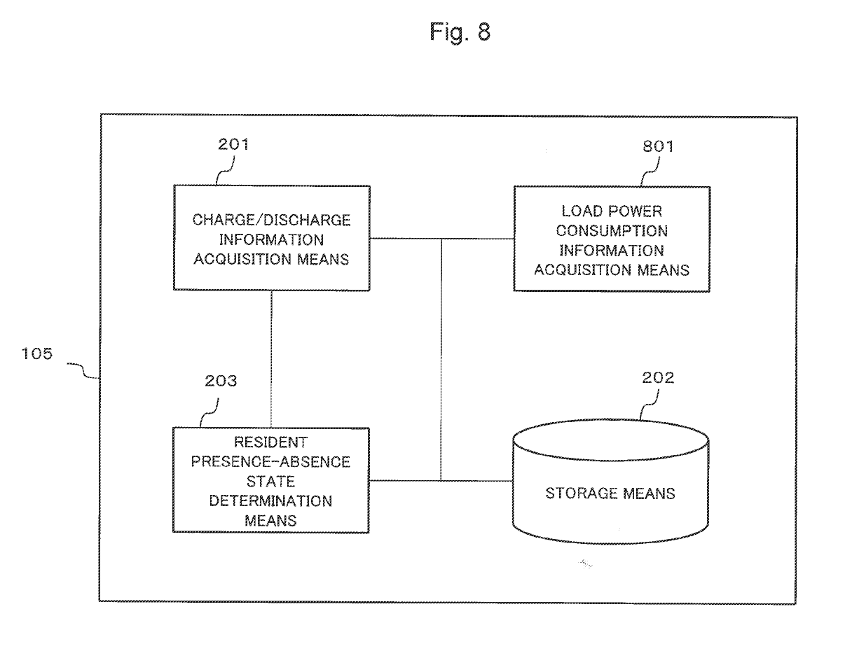

FIG. 8 shows a function block diagram of the resident presence-absence state determination device 105 according to this exemplary embodiment. In this exemplary embodiment, load power consumption information acquisition means 801 is added in the resident presence-absence state determination device 105 according to the third exemplary embodiment. This is a difference between the resident presence-absence state determination device 105 according to the first and second exemplary embodiments and the resident presence-absence state determination device 105 according to the third exemplary embodiment. The operation and function of the charge/discharge information acquisition means 201 are the same as those of the charge/discharge information acquisition means according to the first and second exemplary embodiments.

The load power consumption information acquisition means 801 acquires the information of the power consumption of the load. The information of the power consumption of the load is information indicating an electric power or the electric energy that is consumed by the load (the electric device) 306 placed in the house 100 for each time zone. Namely, the information of the power consumption of the load is information indicating the status of the use of the load 306. The load 306 is not necessarily a load to which the electric power is supplied by the electricity storage device. It may be a load placed in the house 100 and used by the user. When a plurality of the loads exist, the sum of the electric power consumed by the plurality of the loads or the sum of the electric power consumed by the specified loads among the plurality of the loads is used as the information of the power consumption of the load.

The information indicating the electric power consumed by the load 306 for each time zone is for example, a past record value of the electric power consumed by the load, a past record value of the power consumption amount for each time zone, or a predicted value calculated based on these past record values. These past record values are obtained by means (not shown) for measuring the electric power consumed by the load. Further, the electric power consumed by the load can be calculated by using the measured values such as a charged/discharged amount of the electricity storage device, a generated electric power amount of the electric power generation device, the electric power usage (the purchased electric power amount), a sold electric power amount, and the like. For example, it can be calculated by the following calculation formula.

Electric energy consumed by load=Discharged electric energy of electricity storage device−Charged electric energy of electricity storage device+Generated electric energy of electric power generation device+Purchased electric energy−Sold electric energy Formula (1)

The load power consumption information acquisition means 801 acquires load power consumption information from the means for measuring the power consumption of the load or the like. Further, means by which the load power consumption information acquisition means 801 acquires the load power consumption information is not limited in particular. The load power consumption information acquisition means 801 transmits the acquired load power consumption information to the resident presence-absence state determination means 203. Further, the load power consumption information acquisition means 801 transmits the load power consumption information to the storage means 202 and the storage means 202 may store the load power consumption information.

The resident presence-absence state determination means 203 determines the resident presence-absence state by using the load power consumption information and the charge/discharge information. The resident presence-absence state determination means 203 determines that the user is at home when the electricity storage device 101 is in the discharge state and the electric energy consumed by the load is equal to or greater than the reference value. This determination is made on the assumption that when the electric energy consumed by the load is equal to or greater than the predetermined value and the electricity storage device is in the discharge state, another load is used in addition to the load that is always used in the house 100 and whereby, there is a high possibility that the user is at home.

Further, the resident presence-absence state can be determined based on a time elapsing from the discharge start time of the electricity storage device 101, the discharged electric power amount, variation of the electric energy consumed by the load, and the like.

The reference value of the electric energy consumed by the load can be appropriately set. For example, a fifty percent value of the past record value of the electric energy consumed by the load in the predetermined time zone may be set to the reference value. A constant value obtained from the average value of the past record values measured in the same time zone, on the same day of the week, or in the same season in the predetermined past period can be used as the reference value. Alternatively, a predetermined value calculated from the difference between the maximum value and the minimum value of the amount of the power consumption for each time zone can be set to the reference value. Moreover, the user using the electricity storage device 101 can set the reference value. For example, the user may select the load used when the user is at home or a setting mode of the load used when the user is at home and set the reference value of the discharged electric power amount based on the electric energy consumed by the load. Further, the user may select the load always used when the user is not at home and set the reference value based on the electric energy consumed by the load.

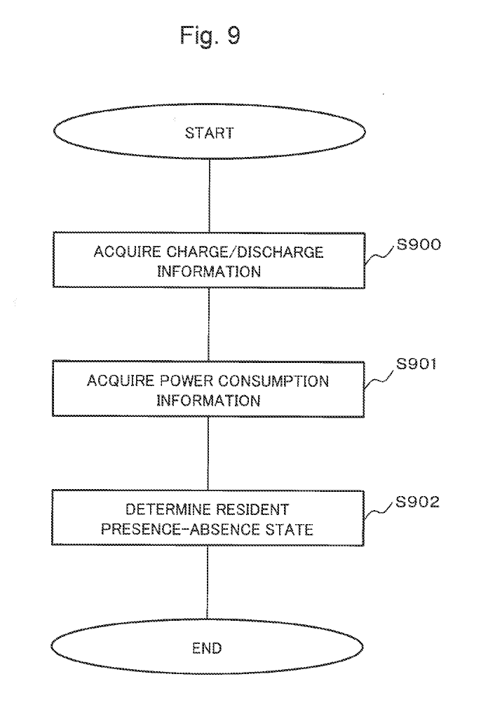

FIG. 9 shows a flow of a process of this exemplary embodiment. In step S900, the charge/discharge information acquisition means 201 acquires the charge/discharge information from the electricity storage device 101 and transmits the charge/discharge information to the resident presence-absence state determination means 203. Next, in step S901, the load power consumption information acquisition means 801 acquires the information of the power consumption of the load from the means for measuring the power consumption of the load and transmit it to the resident presence-absence state determination means 203. The process in step S900 and the process in step S901 can be performed in reverse order. In step S902, the resident presence-absence state determination means 203 determines the resident presence-absence state by using the charge/discharge information and the information of the power consumption of the load. The information of the power consumption of the load is transmitted to the storage means 202 and the storage means 202 may store the information of the power consumption of the load.

This exemplary embodiment has an effect that is similar to those of the first and second exemplary embodiments. Further, when this exemplary embodiment is used, because the resident presence-absence state is determined by using the information of the power consumption of the load, the resident presence-absence state can be more correctly determined.

### Fourth Exemplary Embodiment

In the resident presence-absence state determination device 105 according to a fourth exemplary embodiment, the resident presence-absence state is determined by further using the generated electric power amount of the electric power generation device.

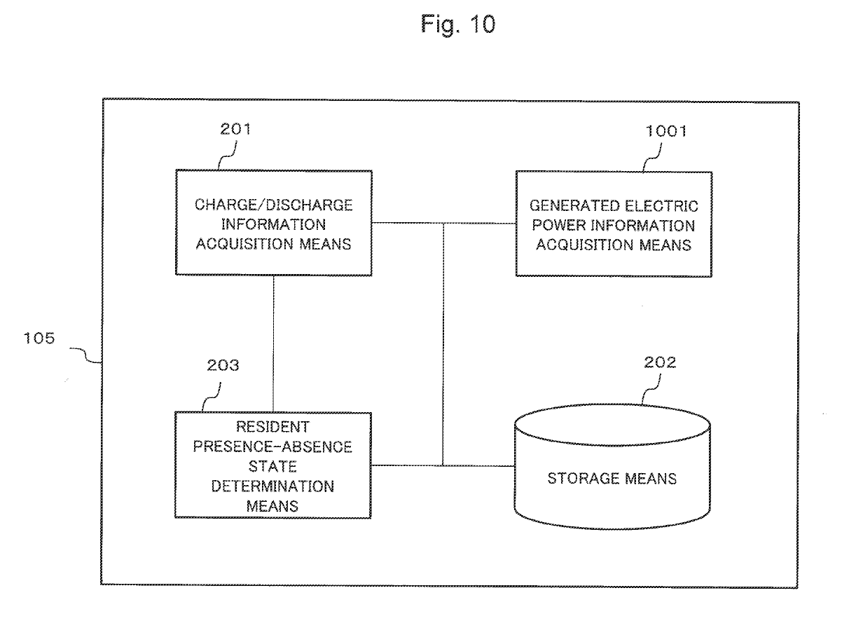

FIG. 10 shows the resident presence-absence state determination device 105 according to this exemplary embodiment. Generated electric power information acquisition means 1001 is added in the resident presence-absence state determination device 105 according to this exemplary embodiment. This is a difference between the resident presence-absence state determination device 105 according to the first to third exemplary embodiments and the resident presence-absence state determination device 105 according to the fourth exemplary embodiment. The operation and function of the charge/discharge information acquisition means 201 according to the fourth exemplary embodiment are the same as those of the charge/discharge information acquisition means according to the first, second, and third exemplary embodiments.

The generated electric power information acquisition means 1001 acquires generated electric power information. The generated electric power information is information indicating the electric energy generated by the electric power generation device which supplies the electric power to the load placed in the house 100 for each time zone with a unit time period. The electric power generation device 307 placed in the house 100 shown in FIG. 2 is an example of the electric power generation device.

The generated electric power information may be for example, the past record value of the electric energy generated by the electric power generation device or a predicted value of an amount of generated electric power that is predicted based on a weather forecast or the like when the electric power generation device using a natural energy is used. The past record value of the electric energy generated by the electric power generation device is measured by means (not shown) for measuring the electric energy generated by the electric power generation device. The generated electric power information acquisition means 1001 acquires the generated electric power information from the means for measuring the amount of generated electric power. The generated electric power information acquisition means 1001 transmits the generated electric power information that is acquired to the resident presence-absence state determination means 203. The generated electric power information acquisition means 1001 transmits the generated electric power information that is acquired to the storage means 202 and the storage means 202 may store the generated electric power information that is received. Further, the generated electric power information acquisition means 1001 can acquire the predicted value of the generated electric power from a server or the like (not shown) which predicts the generated electric power through a communication line. However, a measure to acquire the generated electric power information is not limited in particular.

The resident presence-absence state determination means 203 determines the resident presence-absence state by using the charge/discharge information and the generated electric power information. When the generated electric power amount for each time zone is equal to or greater than the predetermined value (the predetermined value is greater than zero) and the decrease in the amount of the discharged electric power for each time zone is equal to or greater than the predetermined value, the resident presence-absence state determination means 203 determines that the user is at home with respect to the resident presence-absence state in the time zone in which the discharged electric power amount starts to decrease. This is because it can be estimated that when the electric power generated by the electric power generation device increases and can supply the sufficient electric power to the load, a switching operation is performed in order to change a power-supply device for supplying the electric power to the load from the electricity storage device 101 to the electric power generation device. The predetermined value related to the decrease in the amount of the discharged electric power can be appropriately set. For example, the variation between the fifty percent value of the average value (the past record value) of the discharged electric power amount in the time zone and zero of the average value of the discharged electric power amount may be set as the predetermined value based on the record of the discharged electric power for each time zone in a predetermined period.

Further, the resident presence-absence state determination means 203 may compare the generated electric power amount indicated in the generated electric power information with a charged/discharged electric power amount indicated in the charge/discharge information and determine information of resident presence-absence. For example, when the generated electric power amount is equal to or greater than the predetermined value and the electricity storage device 101 stores the electric power equal to or greater than the predetermined value of the generated electric power amount, the resident presence-absence state determination means 203 can determine that the user is not at home. This is because a state in which the generated electric power amount is equal to or greater than the predetermined value and the electricity storage device stores the generated electric power is a state in which the electric power is not consumed in the house 100 and it can be estimated that the user is not at home. Further, the resident presence-absence state can be determined based on various policies using the charge/discharge information and the generated electric power information. Further, the information of the power consumption of the load may be used. Further, the user may appropriately set a condition based on which it is determined whether or not the user is at home based on the generated electric power information, the charge/discharge information, and the information of the power consumption of the load.

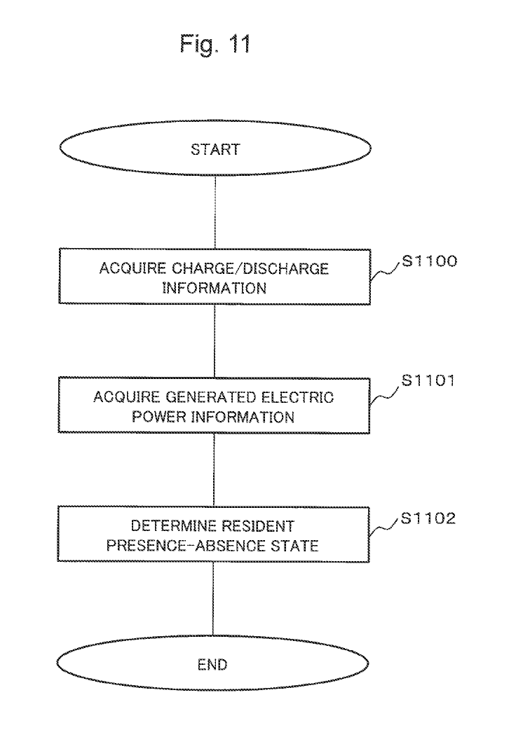

FIG. 11 shows a flow of a process of this exemplary embodiment. In step S1100, the charge/discharge information acquisition means 201 acquires the charge/discharge information. In step S1100, the charge/discharge information acquisition means 201 acquires the charge/discharge information from the electricity storage device 101 through the communication line. The charge/discharge information acquisition means 201 transmit the charge/discharge information to the resident presence-absence state determination means 203. The charge/discharge information acquisition means 201 transmits the charge/discharge information to the storage means 202 and stores it in the storage means 202. In step S1101, the generated electric power information acquisition means 1001 acquires the generated electric power information from the electric power generation device or the like and transmits it to the resident presence-absence state determination means 203. Further, the generated electric power information acquisition means 1001 transmits the generated electric power information to the storage means 202 and stores into the storage means 202. The process in step S1100 and the process in step S1101 can be performed in reverse order. In step S1102, the resident presence-absence state determination means 203 determines the resident presence-absence state by using the charge/discharge information and the generated electric power information.

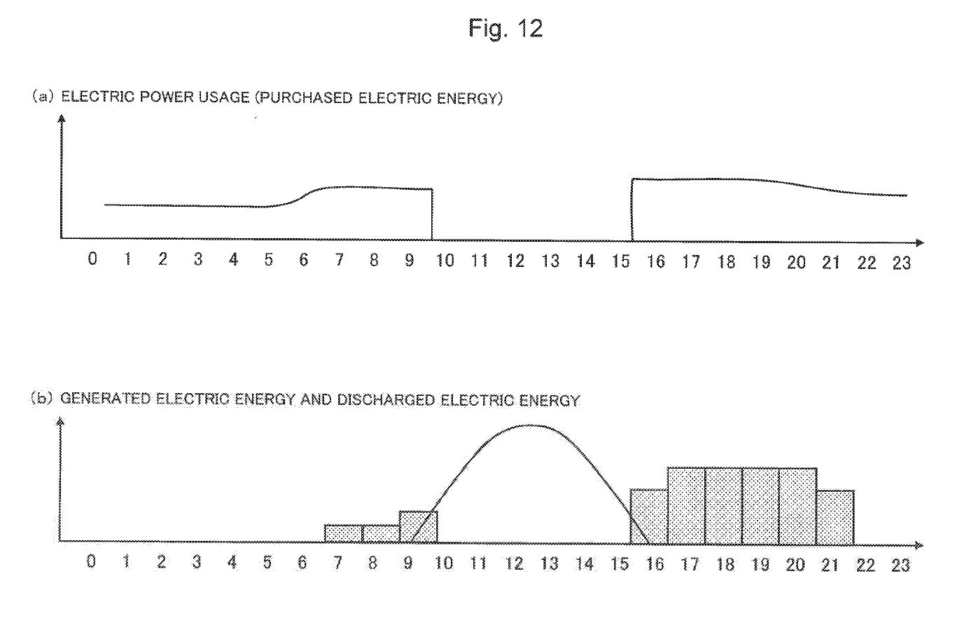

In this exemplary embodiment, the resident presence-absence state is determined by taking into consideration the generated electric power amount of the electric power generation device 307. Therefore, the resident presence-absence state can be more correctly determined. The effect of this exemplary embodiment will be described by using FIG. 12. FIG. 12(a) shows the electric power usage (the purchased electric power amount) in the house 100. It is assumed that the user is at home in the house 100 from 0 am to 11 pm. FIG. 12(a) is a graph of electric power usage (purchased electric power amount) (Wh) versus time. FIG. 12(b) shows the discharged electric power amount (crosshatched bar graph) of the electricity storage device 101 and the generated electric power amount (curve line) of the electric power generation device 307.

Referring to FIG. 12(a), in a time zone from 0 am to 10 am, the electric power usage is restricted to a predetermined value and the shortage of electric power is made up for by the discharge of the electricity storage device 101 (in the time zone from 7 am to 10 am, the electricity storage system supplies the electric power). In the time zone from 10 am to 3 pm, the electric power generation device 307 generates a large electric energy and the generated electric power amount is sufficiently greater than the required electric power amount. Therefore, it is not necessary to supply the electric power of the system to the load (the electric power usage is zero). Further, it is not necessary to supply the electric power of the electricity storage system to the load (the discharged electric power amount is zero). Namely, the electric power required for operating the load is changed to be supplied by only the electric power generation device 307. In such case, when the resident presence-absence state is determined based on a value of the electric power usage, it is determined that the user is not at home because the electric power usage is zero in the time zone from 10 am to 3 pm. On the other hand, when the generated electric power amount for each time zone is equal to or greater than the predetermined value (the predetermined value is greater than zero) and the decrease in the amount of the discharged electric power for each time zone is equal to or greater than the other predetermined value, the resident presence-absence state determination means 203 according to this exemplary embodiment determines that the user is at home with respect to the resident presence-absence state in the time zone in which the discharged electric power amount starts to decrease. Accordingly, it is possible to determine that the user will be at home in the time zone from 10 am to 3 pm.

[Example of Applying to Delivery System]

An example in which the resident presence-absence state determination device of the present invention is applied to a delivery system will be described. FIG. 1 shows an example in which the resident presence-absence state determination device 105 of the present invention is applied to the delivery system. The delivery system of this application example includes the house 100, a housing situation determination device 105 which determines the resident presence-absence state of the house 100, and the terminal 106. The terminal 106 is a terminal used by a delivery company which performs the delivery to the house 100.

The resident presence-absence state determination device 105 is connected to the user's house 100 via the network 104 such as the Internet, a LAN (Local Area Network), and the like and the communication wire 103. The electricity storage device 101 is installed in the house 100. The resident presence-absence state determination device 105 is connected to the terminal 106 via the network 104 and the communication wire 103.

The resident presence-absence state determination device 105 according to this exemplary embodiment is realized by an arbitrary combination of hardware and software mainly such as a CPU (Central Processing Unit) of an arbitrary computer, a memory, a program loaded in the memory, a storage unit such as a hard disk drive for storing the program or the like, and an interface for network connection. Various changes in the realization method and the device can be made and this can be understood by those skilled in the art. Further, the program loaded in the memory includes a program stored in the memory in advance before shipping the device and a program downloaded from a storage medium such as a CD (Compact Disc) or the like, a server on the Internet, or the like.

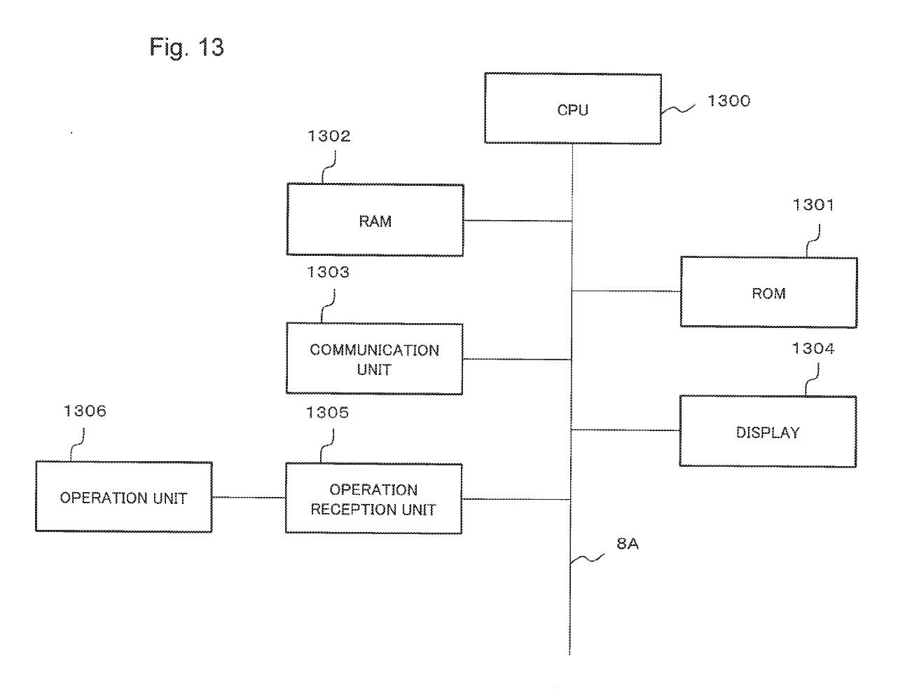

FIG. 13 is a conceptual diagram showing an example of the hardware configuration of the resident presence-absence state determination device 105 described in the first, second, third, and fourth exemplary embodiments. As shown in FIG. 13, the resident presence-absence state determination device 105 includes for example, a CPU 1300, a RAM (Random Access Memory) 1302, a ROM (Read Only Memory) 1301, a communication unit 1303, a display 1304, an operation reception unit 1305, an operation unit 1306, and the like that are connected to each other by a bus 8A. Further, another element (not shown) such as a microphone, a speaker, an auxiliary storage device, or the like may be included in the resident presence-absence state determination device 105.

The CPU 1300 controls each element and also controls the whole computer of the resident presence-absence state determination device 105. The ROM 1301 includes an area in which a program for operating the computer, various application programs, various setting data used when these programs operate, and the like are stored. The RAM 1302 includes an area for temporarily storing data such as a work area in which the program operates or the like.

The operation unit 1306 includes an operation key, an operation button, a switch, a jog dial, a touch pad, a touch panel integrally formed with a display, or the like. The operation reception unit 1305 receives a user's input entered when the user operates the operation unit 1306.

The communication unit 1303 can be connected to the network such as the Internet, the LAN (Local Area Network), or the like. Further, the communication unit 1303 is connected to an external device in a one-to-one manner and can communicate with the external device. The communication unit 1303 can be connected to the external device and the network by using a wired line and/or all the wireless communication technologies (such as Near Field Communication, wireless LAN communication, and the like).

The display 1304 includes an LED (Light Emitting Diode) indicator, a liquid crystal display, an organic EL (Electro Luminescence) display, or the like.

Next, the house 100 will be described. The house 100 is a detached house, a collective housing, a store, a business office, a school, a public facility, or the like. The house 100 is a unit for which the resident presence-absence state (existence of human) has to be determined. FIG. 2 shows an example of the house 100. Referring to FIG. 2, the electric power supplied from the electric power system 301 and the electric power generation device 307 is stored in the electricity storage device 101 and the electricity storage device 101 supplies the stored electric power to the load 306.

The load 306 receives the electric power from the system 301, the electricity storage device 101, and the electric power generation device 307.

The electricity storage device 101 includes for example, the storage battery 302, the BMU (Battery Management Unit) 303, the PCS (Power Conditioning System) 304, and the system controller 305.

The storage battery 302 includes a plurality of battery cells connected in series and/or in parallel and is configured so as to store electric power. The battery cell is a secondary battery such as a lithium-ion secondary battery, a lead storage battery, a nickel hydride battery, or the like.

The BMU 303 protects and controls the storage battery 302. The PCS 304 is connected to the BMU 303, the electric power system 301, the load 306, and the electric power generation device 307, converts direct current electric power to alternating current electric power, and adjusts a voltage and a frequency. The electric power system 301 is a system which is managed by an electric power supplier (for example, an electric power company or the like) and supplies the electric power to an electric power consumer. The electric power generation device 307 is the device managed by each electric power consumer and the type of the electric power generation device 307 is not limited in particular. For example, the electric power generation device 307 may be a device for generating electricity by using a natural energy such as sunlight or the like.

The system controller 305 performs unified management of the BMU 303 and the PCS 304. The system controller 305 is connected to the network such as the Internet, the LAN, or the like and transmits/receives the data to/from the resident presence-absence state determination device 105.

Further, in FIG. 2, the storage battery 302, the BMU 303, the PCS 304, and the system controller 305 are shown as separate elements. However, this figure shows that these four elements are logically separated from each other. These modules may also be physically separated from each other or an arbitrary combination of some of these modules may be integrally formed. For example, the storage battery 302 and the BMU 303 may be installed in one chassis.

The terminal 106 is a terminal used by the delivery company. The example of the hardware configuration of the terminal 106 is similar to the hardware configuration shown in FIG. 13. Therefore, the description will be omitted. The terminal 106 may be set in the business office of the delivery company or carried by a delivery person (a delivery driver or the like) which performs the delivery.

In this system, the terminal 106 transmits the resident presence-absence state determination request in which the expected delivery time (or time zone) to the house 100 is specified to the resident presence-absence state determination device 105. The resident presence-absence state determination device 105 acquires the charge/discharge information from the electricity storage device 101 based on the resident presence-absence state determination request and determines the resident presence-absence state of the house 100 at the specified time. The determination of the resident presence-absence state is made when the user agrees. The user enters information (also referred to as user permission information) indicating whether or not the user permits the provision of the charge/discharge information of the electricity storage device 101 and the determination of the resident presence-absence state by using input means of the electricity storage device 101. The user permission information is transmitted to the resident presence-absence state determination device 105 through the communication line and stored in the storage means 202. The user permission may be obtained whenever the resident presence-absence state is determined or at a start time of using the electricity storage device 101. Further, the user can determine whether or not the user permits the determination of the resident presence-absence state for each terminal to which a determination result is transmitted.

The resident presence-absence state determination device 105 acquires the user permission information accumulated in the storage means 202 and determines the resident presence-absence state of the house 100 to which the user permits the determination of the resident presence-absence state. The determination is made by using any one of the methods described in the first to fourth exemplary embodiments or a combination of these methods. The resident presence-absence state determination device 105 notifies the terminal 106 of the determination result of the resident presence-absence state.

The delivery company performs the delivery to the house 100 based on the resident presence-absence state of which the terminal 106 is notified. The terminal 106 designs a delivery route and a delivery schedule based on the resident presence-absence states of a plurality of the houses 100. For example, the terminal 106 designs the delivery route so that a delivery can be performed to the house 100 in the time zone in which it is determined that the user is at home among the houses 100 that are the delivery destinations. The delivery route can be designed by using the various known methods. Further, when the resident presence-absence state is updated, the delivery route may be redesigned by using the updated resident presence-absence state. The method of updating the delivery route is not limited in particular. The delivery route may be designed by another device other than the terminal 106. The designed delivery route is outputted through for example, the display of the terminal 106 or the like.

The exemplary embodiment of the present invention has been described above with reference to the drawing. However, these exemplary embodiments are described as an example and a combination of these exemplary embodiments or another configuration other than the above-mentioned configuration can be used.

The present invention has been described above by using the exemplary embodiment as an exemplary example. However, the present invention is not limited to the exemplary embodiment mentioned above. Namely, various changes in the configuration or details of the invention of the present application that can be understood by those skilled in the art can be made without departing from the scope of the invention of the present application.

This application claims priority from Japanese Patent Application No. 2014-027686 filed on Feb. 17, 2014, the disclosure of which is hereby incorporated by reference in its entirety.

### REFERENCE SIGNS LIST

100 house
101 electricity storage device
103 communication wire
104 network
105 resident presence-absence state determination device
106 terminal
201 charge/discharge information acquisition means
202 storage means
203 resident presence-absence state determination means
301 electric power system
302 storage battery
303 BMU
304 PCS
305 system controller
306 load
307 electric power generation device
801 load power consumption information acquisition means
1001 generated electric power information acquisition means
1300 CPU
1301 ROM
1302 RAM
1303 communication unit
1304 display
1305 operation reception unit
1306 operation unit.

1. A resident presence-absence state determination device comprising:
a charge/discharge information acquisition unit that acquires charge/discharge information indicating a charging status or a discharging status of an electricity storage device for supplying an electric power to a load placed in a house; and
a resident presence-absence state determination unit that determines a presence-absence state of a residence in the house based on the charge/discharge information.

2. The resident presence-absence state determination device according to claim 1, wherein
the charge/discharge information is information that indicates that the electricity storage device is in a discharge state and
the resident presence-absence state determination unit determines that a resident is in the house when the electricity storage device is in the discharge state.

3. The resident presence-absence state determination device according to claim 1, wherein
the charge/discharge information includes a discharge start time and a discharge end time of the electricity storage device and
the resident presence-absence state determination unit determines that the resident is in the house in a period from the discharge start time to the discharge end time.

4. The resident presence-absence state determination device according to claim 1, wherein
the charge/discharge information is information about a discharged electric energy of the electricity storage device in each a unit time period, and
the resident presence-absence state determination unit determines that the resident is in the house in the time period in which the discharged electric energy is equal to or greater than a predetermined electric energy.

5. The resident presence-absence state determination device described in claim 4, wherein the resident presence-absence state determination unit determines the resident presence-absence state based on variation of the discharged electric energy.

6. The resident presence-absence state determination device according to claim 1, wherein the resident presence-absence state determination unit predicts the discharging status at a specified future time based on the charge/discharge information and determine the resident presence-absence state at the future time by using a result of the prediction.

7. The resident presence-absence state determination device according to claim 1, wherein
the resident presence-absence state determination device further includes load power consumption information acquisition unit that acquires information about the power consumption of the load which indicates an electric power or an electric energy consumed by the load placed in the house and
the resident presence-absence state determination means determine the resident presence-absence state based on the charge/discharge information and the information about the power consumption of the load.

8. The resident presence-absence state determination device according to claim 7, wherein
the resident presence-absence state determination unit determines that the resident is at home when the electricity storage device is in the discharge state and the power consumption of the load is equal to or greater than a predetermined value.

9. The resident presence-absence state determination device according to claim 1, wherein
the resident presence-absence state determination device further includes a generated electric power information acquisition unit that acquires generated electric power information indicating an electric power or electric energy that is generated by an electric power generation device which supplies the electric power to the load placed in the house and
the resident presence-absence state determination unit determines the resident presence-absence state based on the charge/discharge information and the generated electric power generation information.

10. The resident presence-absence state determination device according to claim 9, wherein
the resident presence-absence state determination unit determines that the resident is in the house when the generated electric energy is equal to or greater than a predetermined value and a decrease in the discharged electric energy is equal to or greater than a predetermined value.

11. A delivery system comprising
an electricity storage unit that supplies an electric power to a load placed in a house that is a delivery destination,
a charge/discharge information acquisition unit that acquires charge/discharge information indicating a charging status or a discharging status of the electricity storage unit,
a resident presence-absence state determination unit that determines resident presence-absence state of the house based on the charge/discharge information, and
an output unit that outputs a delivery route including the house as to which the resident presence-absence state is determined that the resident is present in the house.

12. A method for determining a resident presence-absence state comprising:
acquiring charge/discharge information indicating a charging status or a discharging status of an electricity storage device which supplies an electric power to a load placed in a house and
determining a presence-absence state of a resident in the house based on the charge/discharge information.

13. A non-transitory computer-readable recording medium recording a program which causes a computer to function as a resident presence-absence state determination device which determines a resident presence-absence state of a house wherein the recording medium records a program for determining the resident presence-absence state which causes the computer to perform
a process to acquire a charge/discharge information indicating a charging status or a discharging status of an electricity storage device which supplies an electric power to a load placed in the house and
a process to determine the presence-absence state of a resident in the house based on the charge/discharge information.

14. A terminal for use in a delivery system comprising
a transmitter that transmits a request in which a house that is a delivery destination and a delivery time at which a delivery is performed to the delivery destination are specified,
means for receiving an presence-absence state of a resident in the house, the presence-absence state being determined based on charge/discharge information indicating a charging status or a discharging status of an electricity storage device for supplying an electric power to a load placed in the house and
an output unit that outputs a delivery route including the house as to which the presence-absence state is determined that the resident is present in the house.

15. A resident presence-absence state determination device comprising
charge/discharge information acquisition means for acquiring charge/discharge information indicating a charging status or a discharging status of an electricity storage device for supplying an electric power to a load placed in a house and
presence-absence state determination means for determining a presence-absence state of a resident in the house based on the charge/discharge information.
